(19) United States
(12) Patent Application Publication
(10) Pub. No.: US 2021/0359231 A1
(43) Pub. Date: Nov. 18, 2021

(54) FLEXIBLE DISPLAY DEVICE

(71) Applicant: Shenzhen China Star Optoelectronics Semiconductor Display Technology Co., Ltd., Shenzhen (CN)

(72) Inventor: LIU Zhaosong, Shenzhen (CN)

(21) Appl. No.: 16/323,755

(22) PCT Filed: Dec. 14, 2018
(86) PCT No.: PCT/CN2018/121167

§ 371 Date: Feb. 6, 2019

(30) Foreign Application Priority Data
Oct. 15, 2018 (CN) 201811198287.8

(51) Int. Cl. H01L 51/00; H01L 27/32; H01L 51/52

(52) U.S. Cl. CPC H01L 51/0097; H01L 27/3246; H01L 2227/323; H01L 27/3211; H01L 2251/5338; H01L 51/5237

(57) ABSTRACT

A flexible display device comprising a flexible substrate, a buffer layer, an active layer, a gate insulating layer, a gate metal layer, an interlayer insulating layer, a source/drain metal layer, a passivation layer, an anode metal layer, a pixel defining layer, an OLED light emitting layer, and an encapsulation layer; wherein the interlayer insulating layer is formed with a via hole, the source/drain metal layer is connected to the active layer through the via hole; a material of the pixel defining layer is a polymer organic polymer with a high Young's modulus.

### CROSS REFERENCE TO RELATED APPLICATION

This application claims the priority of International Application No. PCT/CNPCT/CN2018/121167, filed on 2018 Dec. 14, which claims priority to Chinese Application No. 201811198287.8, filed on 2018 Oct. 15. The entire disclosures of each of the above applications are incorporated herein by reference.

### BACKGROUND OF INVENTION

### Field of Invention

The present invention relates to the field of display technologies, and in particular, to a flexible display device.

### Description of Prior Art

At present, active matrix organic light emitting diode (AMOLED) display technology has the advantages of having wide color gamut, being self-luminous, thin, light, fast response times, and bendability, etc. Generally, AMOLED displays can be classified into rigid display devices and flexible display devices. Display technology of flexible display devices gives wearable electronic devices unlimited potential. Compared with the rigid display devices, display units (especially inside a bent region) of the flexible display device are subjected to higher stress under compressive pressure or deflection, which is liable to damage the display units (including thin film transistors and display lighting units) and greatly shorten service life thereof. Therefore, improving the pressure/compression resistance of a flexible display device is an important way to increase its service life.

In summary, existing flexible display devices can easily cause damage to the thin film transistors and the display lighting unit in a compressive stress or a flexed state, and further shortens the service life of the flexible display devices.

### SUMMARY OF INVENTION

The present application provides a flexible display device capable of dispersing stress applied to a flexible display device, and solves the problem of the existing flexible display device can easily cause damages to the thin film transistors and the display lighting unit in a compressive stress or a flexed state, and further shortens the service life of the flexible display device.

To solve the above problems, the technical solutions provided by the present application are as follows:

The present application provides a flexible display device comprising a flexible substrate, a buffer layer, an active layer, a gate insulating layer, a gate metal layer, an interlayer insulating layer, a source/drain metal layer, a passivation layer, an anode metal layer, and a pixel defining layer, an OLED light emitting layer and an encapsulation layer;

wherein the interlayer insulating layer is formed with a via hole, the source/drain metal layer is connected to the active layer through the via hole; the material of the pixel defining layer is a polymer organic polymer with a high Young's modulus, and the high molecular organic polymer is polydimethylsiloxane.

In the flexible display device provided by an embodiment of the present application, the pixel defining layer is formed by a nano-transfer printing method.

In the flexible display device provided by an embodiment of the present application, the via hole extends through the interlayer insulating layer and is terminated at the active layer.

In the flexible display device provided by an embodiment of the present application, the OLED light emitting layer comprises a red sub-pixel light emitting layer, a green sub-pixel light emitting layer, and a blue sub-pixel light emitting layer.

In the flexible display device provided by an embodiment of the present application, a material of the flexible substrate is polyimide or polyethylene terephthalate, a material of the buffer layer is one or two of silicon nitride or silicon oxide, a material of the gate insulating layer is silicon nitride or silicon oxide.

In the flexible display device provided by an embodiment of the present application, a material of the gate metal layer is molybdenum, a material of the source/drain metal layer is titanium or titanium aluminum alloy.

In the flexible display device provided by an embodiment of the present application, the encapsulation layer comprises a first inorganic encapsulation layer, a first organic encapsulation layer, and a second inorganic encapsulation layer disposed in a stack.

In the flexible display device provided by an embodiment of the present application, the material of the first inorganic encapsulating layer is one or a combination of two or more of silicon nitride, silicon dioxide, aluminum oxide, titanium oxide, and zirconium dioxide, and the material of the second inorganic encapsulation layer is the same as the material of the first inorganic encapsulation layer.

The present application also provides a flexible display device comprising a flexible substrate, a buffer layer, an active layer, a gate insulating layer, a gate metal layer, an interlayer insulating layer, a source/drain metal layer, a passivation layer, an anode metal layer, and a pixel defining layer, an OLED light emitting layer and an encapsulation layer;

wherein the interlayer insulating layer is formed with a via hole, the source/drain metal layer is connected to the active layer through the via hole; and the material of the pixel defining layer is a polymer organic polymer with a high Young's modulus.

In the flexible display device provided by an embodiment of the present application, the pixel defining layer is formed by a nano-transfer printing method.

In the flexible display device provided by an embodiment of the present application, the via hole extends through the interlayer insulating layer and is terminated at the active layer.

In the flexible display device provided by an embodiment of the present application, the OLED light emitting layer comprises a red sub-pixel light emitting layer, a green sub-pixel light emitting layer, and a blue sub-pixel light emitting layer.

In the flexible display device provided by an embodiment of the present application, a material of the flexible substrate is polyimide or polyethylene terephthalate, a material of the buffer layer is one or two of silicon nitride or silicon oxide, a material of the gate insulating layer is silicon nitride or silicon oxide.

In the flexible display device provided by an embodiment of the present application, a material of the gate metal layer is molybdenum, a material of the source/drain metal layer is titanium or titanium aluminum alloy.

In the flexible display device provided by an embodiment of the present application, the encapsulation layer comprises a first inorganic encapsulation layer, a first organic encapsulation layer, and a second inorganic encapsulation layer disposed in a stack.

In the flexible display device provided by an embodiment of the present application, the material of the first inorganic encapsulating layer is one or a combination of two or more of silicon nitride, silicon dioxide, aluminum oxide, titanium oxide, and zirconium dioxide, and the material of the second inorganic encapsulation layer is the same as the material of the first inorganic encapsulation layer.

The advantages of the application includes: the flexible display device provided by the present application sets the pixel defining layer as a high molecular organic polymer having a high Young's modulus, which could disperse the applied stress in the flexible display device, protect the OLED light emitting device, and further improve the service life of the flexible display device.

### BRIEF DESCRIPTION OF DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a structural diagram of a flexible display device of the present application.

FIG. 2 is a flowchart of a method for manufacturing a flexible display device of the present application.

FIG. 3A to FIG. 3C are structural diagrams showing a manufacturing method of the flexible display device of FIG. 2.

### DETAILED DESCRIPTION OF PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

The present application provides a flexible display device capable of dispersing stress applied to a flexible display device, and solves the problem of the existing flexible display device can easily cause damages to the thin film transistors and the display lighting unit in a compressive stress or a flexed state, and further shortens the service life of the flexible display device.

As shown in FIG. 1, the present application provides a flexible display device comprising a flexible substrate 101, a buffer layer 102, an active layer 103, a gate insulating layer 104, a gate metal layer 105, an interlayer insulating layer 106, a source/drain metal layer 108, a passivation layer 109, an anode metal layer 110, and a pixel defining layer 111, an organic light emitting diode (OLED) light emitting layer 112, and an encapsulation layer 113.

Wherein, the interlayer insulating layer 106 is formed with a via hole 107, the source/drain metal layer 108 is connected to the active layer 103 through the via hole 107; the material of the pixel defining layer 111 is a polymer organic polymer with a high Young's modulus.

Specifically, the high molecular organic polymer is polydimethylsiloxane; the polydimethylsiloxane has a high Young's modulus and can support the flexible display device well, and the applied stress (compacting/bending stress) is dispersed, thereby the flexible display device can be well protected.

Specifically, the pixel defining layer 111 further comprises a black dye; the black dye is used to form the black pixel defining layer 111, the black pixel defining layer 111 is advantageous for blocking lateral light leakage between adjacent sub-pixels and improving the contrast of the flexible display device.

Specifically, the pixel defining layer 111 is prepared by a nano-transfer printing method.

Specifically, the via hole 107 extends through the interlayer insulating layer 106 and is terminated in the active layer 103; the via 107 is formed on the interlayer insulating layer 106 for the purpose of allowing the source/drain metal layer 108 to communicate with the active layer 103.

Specifically, the OLED light emitting layer 112 comprises a red sub-pixel light emitting layer 1121, a green sub-pixel light emitting layer 1122, and a blue sub-pixel light emitting layer 1123.

A material of the flexible substrate 101 is polyimide or polyethylene terephthalate; a material of the buffer layer 102 is one or two of silicon nitride or silicon oxide, and the buffer layer 102 has a thickness of is 3000 angstroms; a material of the gate insulating layer 104 is silicon nitride or silicon oxide, and the gate insulating layer 104 has a thickness of 1000 angstroms; the interlayer insulating layer 106 has a thickness of 3000 angstroms; a material of the source/drain metal layer 108 is titanium or titanium aluminum alloy; a material of the gate metal layer 105 is molybdenum, and a material of the anode metal layer 110 is indium tin oxide (ITO).

Specifically, the encapsulation layer 113 comprises a first inorganic encapsulation layer 1131, a first organic encapsulation layer 1132, and a second inorganic encapsulation layer 1133; a material of the first inorganic encapsulating layer 1131 is a combination of one or two or more of silicon nitride, silicon dioxide, aluminum oxide, titanium oxide, and zirconium dioxide, a material of the second inorganic encapsulation layer 1133 is the same as the material of the first inorganic encapsulation layer 1131.

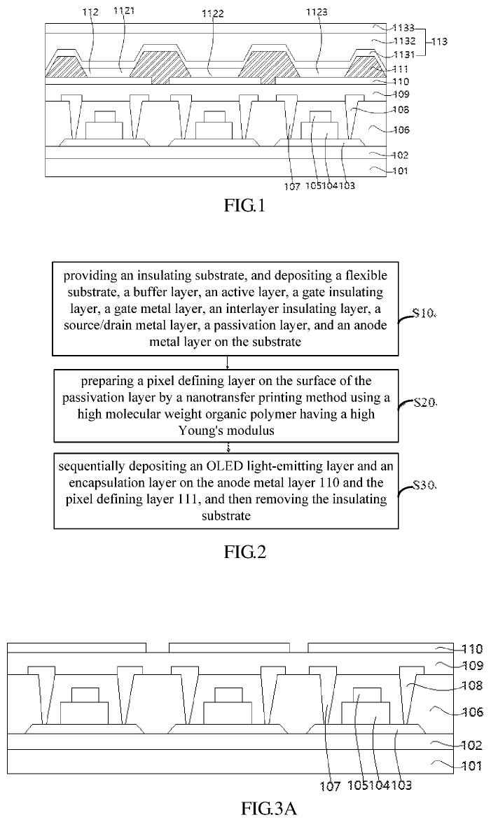

As shown in FIG. 2, provides a flow chart of a method for manufacturing a flexible display device of the present application, the method comprising:

Step S10, providing an insulating substrate, and depositing a flexible substrate 101, a buffer layer 102, an active layer 103, a gate insulating layer 104, a gate metal layer 105, an interlayer insulating layer 106, a source/drain metal layer 108, a passivation layer 109, and an anode metal layer 110 on the substrate.

Specifically, the S10 further includes the following features.

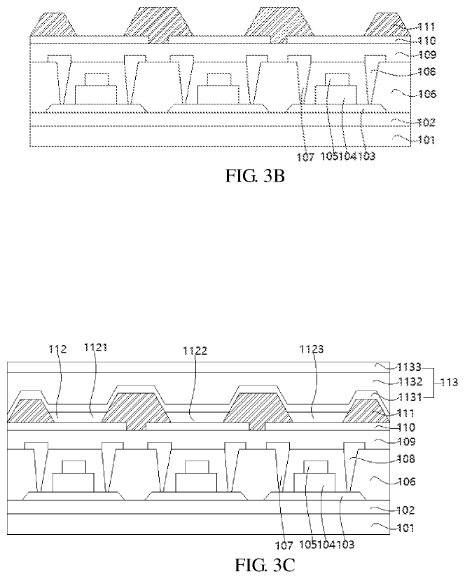

First, an insulating substrate is provided, and a flexible substrate 101 is deposited on the surface of the insulating substrate, and a material of the flexible substrate 101 is polyimide or polyethylene terephthalate; thereafter, a buffer layer 102 is deposited on the surface of the flexible substrate 201 using chemical weather deposition; a material of the buffer layer 102 is one or two of silicon nitride or silicon oxide, and the buffer layer 102 has a thickness of 3000 angstroms; thereafter, a semiconductor layer is formed on the surface of the buffer layer 102, a reticle lithography process is used to define the semiconductor layer structure and forming an active layer 103; then depositing a gate insulating layer 104 on the surface of the buffer layer 102, the gate insulating layer 104 completely covers the active layer 103, a material of the gate insulating layer 104 is silicon nitride or silicon oxide, and the thickness of the gate insulating layer 104 is 1000 angstroms; then forming a gate conductor structure on the surface of the gate insulating layer 104 by a reticle lithography process, and forming a gate metal layer 105, the gate metal layer 105 is made of metal molybdenum; then forming an interlayer insulating layer 106 on the surface of the buffer layer 102, and then forming a via 107 on the surface of the interlayer insulating layer 106; then, a source/drain conductor structure is defined on the via 107 by a reticle lithography process to form a source/drain metal layer 108, the source/drain metal layer 108 is in communication with the active layer 103 through the via 107, and the material of the source/drain metal layer 108 is titanium or titanium aluminum alloy; finally, a passivation layer 109 and an anode metal layer 110 are sequentially formed on the surface of the interlayer insulating layer 106, and the material of the anode metal layer 110 is ITO, as shown in FIG. 3A.

Step S20, preparing a pixel defining layer 111 on the surface of the passivation layer 109 by a nano-transfer printing method using a high molecular weight organic polymer having a high Young's modulus.

Specifically, the S20 further includes the following features.

The pixel defining layer 111 is located on a surface of the passivation layer 109 and covers both ends of the edge of the anode metal layer 110; a material of the pixel defining layer 111 is a high Young's modulus polymer, specifically polydimethylsiloxane; the polydimethylsiloxane has a high Young's modulus and can support the flexible display device well, and the applied stress (compacting/bending stress) is dispersed, thereby the flexible display device can be well protected. The pixel defining layer 111 further comprises a black dye; the black dye is used to form the black pixel defining layer 111, the black pixel defining layer 111 is advantageous for blocking lateral light leakage between adjacent sub-pixels and improving the contrast of the flexible display device, as shown in FIG. 3B.

Step S30, sequentially depositing an OLED light-emitting layer and an encapsulation layer on the anode metal layer 110 and the pixel defining layer 111, and then removing the insulating substrate.

Specifically, the S30 further includes the following features.

The OLED light emitting layer 112 comprises a red sub-pixel light emitting layer 1121, a green sub-pixel light emitting layer 1122, and a blue sub-pixel light emitting layer 1123. The encapsulation layer 113 comprises a first inorganic encapsulation layer 1131, a first organic encapsulation layer 1132, and a second inorganic encapsulation layer 1133; a material of the first inorganic encapsulating layer 1131 is a combination of one or two or more of silicon nitride, silicon dioxide, aluminum oxide, titanium oxide, and zirconium dioxide, a material of the second inorganic encapsulation layer 1133 is the same as a material of the first inorganic encapsulation layer 1131, as shown in FIG. 3C.

The advantages of the application includes the flexible display device provided by the present application sets the pixel defining layer as a high molecular organic polymer having a high Young's modulus, which could disperse the applied stress in the flexible display device, protect the OLED light emitting device, and further improve the service life of the flexible display device.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. A flexible display device, comprising:
a flexible substrate;
a buffer layer disposed on a surface of the flexible substrate;
an active layer disposed on a surface of the buffer layer;
a gate insulating layer disposed on a surface of the active layer;
a gate metal layer disposed on a surface of the gate insulating layer;
an interlayer insulating layer disposed on the surface of the buffer layer and completely covering the active layer, the gate insulating layer, and the gate metal layer, and the interlayer insulating layer is formed with a via hole;
a source/drain metal layer disposed on the interlayer insulating layer, and the source/drain metal layer is connected to the active layer through the via hole;
a passivation layer disposed on a surface of the interlayer insulating layer and completely covering the source/drain metal layer;
an anode metal layer disposed on a surface of the passivation layer;
a pixel defining layer disposed on the surface of the passivation layer and covering both ends of an edge of the anode metal layer;
an organic light emitting diode (OLED) light emitting layer disposed on a surface of the anode metal layer;
an encapsulation layer disposed on a surface of the passivation layer and completely covering the pixel defining layer and the OLED light emitting layer;
wherein, the material of the pixel defining layer is a polymer organic polymer with a high Young's modulus, and the high molecular organic polymer is polydimethylsiloxane.

2. The flexible display device according to claim 1, wherein the pixel defining layer further comprises a black dye.

3. The flexible display device according to claim 1, wherein the pixel defining layer is formed by a nano-transfer printing method.

4. The flexible display device according to claim 1, wherein the via hole extends through the interlayer insulating layer and is terminated at the active layer.

5. The flexible display device according to claim 1, wherein the OLED light emitting layer comprises a red sub-pixel light emitting layer, a green sub-pixel light emitting layer, and a blue sub-pixel light emitting layer.

6. The flexible display device according to claim 1, wherein a material of the flexible substrate is polyimide or polyethylene terephthalate, a material of the buffer layer is one or two of silicon nitride or silicon oxide, a material of the gate insulating layer is silicon nitride or silicon oxide.

7. The flexible display device according to claim 1, wherein a material of the gate metal layer is molybdenum, a material of the source/drain metal layer is titanium or titanium aluminum alloy.

8. The flexible display device according to claim 1, wherein the encapsulation layer comprises a first inorganic encapsulation layer, a first organic encapsulation layer, and a second inorganic encapsulation layer disposed in a stack.

9. The flexible display device according to claim 8, wherein the material of the first inorganic encapsulating layer is one or a combination of two or more of silicon nitride, silicon dioxide, aluminum oxide, titanium oxide, and zirconium dioxide, and the material of the second inorganic encapsulation layer is the same as the material of the first inorganic encapsulation layer.

10. A flexible display device, comprising:
a flexible substrate;
a buffer layer disposed on a surface of the flexible substrate;
an active layer disposed on a surface of the buffer layer;
a gate insulating layer disposed on a surface of the active layer;
a gate metal layer disposed on a surface of the gate insulating layer;
an interlayer insulating layer disposed on the surface of the buffer layer, and completely covers the active layer, the gate insulating layer, and the gate metal layer, wherein the interlayer insulating layer is formed with a via hole;
a source/drain metal layer on the interlayer insulating layer, and the source/drain metal layer is connected to the active layer through the via hole;
a passivation layer disposed on a surface of the interlayer insulating layer and completely covers the source/drain metal layer;
an anode metal layer disposed on a surface of the passivation layer;
a pixel defining layer disposed on a surface of the passivation layer and covering both ends of an edge of the anode metal layer;
an organic light emitting diode (OLED) light emitting layer disposed on a surface of the anode metal layer;
an encapsulation layer disposed on the surface of the passivation layer and completely covering the pixel defining layer and the OLED light emitting layer; and
a material of the pixel defining layer is a polymer organic polymer with a high Young's modulus.

11. The flexible display device according to claim 10, wherein the pixel defining layer further comprises a black dye.

12. The flexible display device according to claim 10, wherein the pixel defining layer is formed by a nano-transfer printing method.

13. The flexible display device according to claim 10, wherein the via hole extends through the interlayer insulating layer and is terminated at the active layer.

14. The flexible display device according to claim 10, wherein the OLED light emitting layer comprises a red sub-pixel light emitting layer, a green sub-pixel light emitting layer, and a blue sub-pixel light emitting layer.

15. The flexible display device according to claim 10, wherein a material of the flexible substrate is polyimide or polyethylene terephthalate, a material of the buffer layer is one or two of silicon nitride or silicon oxide, and a material of the gate insulating layer is silicon nitride or silicon oxide.

16. The flexible display device according to claim 10, wherein a material of the gate metal layer is molybdenum, and a material of the source/drain metal layer is titanium or titanium aluminum alloy.

17. The flexible display device according to claim 10, wherein the encapsulation layer comprises a first inorganic encapsulation layer, a first organic encapsulation layer, and a second inorganic encapsulation layer disposed in a stack.

18. The flexible display device according to claim 17, wherein a material of the first inorganic encapsulating layer is one or a combination of two or more of silicon nitride, silicon dioxide, aluminum oxide, titanium oxide, and zirconium dioxide, and a material of the second inorganic encapsulation layer is the same as the material of the first inorganic encapsulation layer.
